(19) United States
(12) Patent Application Publication
(10) Pub. No.: US 2026/0259587 A1
(43) Pub. Date: Sep. 3, 2026

(54) ELECTRONIC CIRCUIT AND METHOD FOR POWERING MULTIPLE ELECTRONIC SYSTEMS OF AN ELECTRONIC CONTROL UNIT OF A VEHICLE, AND ELECTRONIC CONTROL ARRANGEMENT OF A VEHICLE

(71) Applicant: CONNAUGHT ELECTRONICS Ltd., Tuam, County Galway (IE)

(72) Inventors: Chup-Chung Wong, Tuam (IE); Raghavendra Shanbhag, Tuam (IE); Brian Somers, Tuam (IE)

(73) Assignee: CONNAUGHT ELECTRONICS Ltd., Tuam, County Galway (IE)

(21) Appl. No.: 18/880,112

(22) PCT Filed: Jun. 29, 2023
(86) PCT No.: PCT/EP2023/067785

§ 371 Date: Dec. 30, 2024

(30) Foreign Application Priority Data
Jun. 29, 2022 (DE) 10 2022 116 145.5

(51) Int. Cl. G06F 1/24; B60R 16/03; G06F 1/3287; H03K 17/20

(52) U.S. Cl. CPC G06F 1/24; B60R 16/03; G06F 1/3287; H03K 17/20

(57) ABSTRACT

An electronic circuit for powering multiple electronic systems of an electronic control unit of a vehicle includes a power input detector, multiple latches, and multiple power management circuitry. The power input detector is configured to detect an input voltage and to generate a first set signal depending on the detected input voltage. The output of the power input detector is connected to a respective set input of each of the multiple latches. Each of the multiple latches is configured to generate a respective enable signal depending on the first set signal. Each latch is connected to its associated power management circuitry. Each of the multiple power management circuitries is configured to power its associated electronic system depending on the enable signal.

The present invention is directed to an electronic circuit for powering multiple electronic systems of an electronic control unit of a vehicle. The invention is further directed to a method for powering multiple electronic systems in an electronic control unit of a vehicle. The invention further relates to an electronic control arrangement comprising an electronic circuit according to the invention.

Recent developments of an electronic control unit (ECU) for Advanced Driver Assistance Systems (ADAS) and Autonomous Driving Systems (ADS) require very high computational power to fulfill the needs of understanding the surroundings around the self-driving vehicle. The ECU has to be designed in accordance with high functional safety requirements so that sufficient redundancy is built in the system to achieve safe self-driving capabilities. In this connection, the ECU may be designed with multiple electronic systems, e.g. microprocessors or multiple Systems-on-Chip (SoCs). For example, these SoCs have to complete their boot up processes in a very short time, e.g. less than two seconds to satisfy the Federal Motor Vehicle Safety Standards (FMVSS), especially FMVSS-111, and be ready for any fully automatic or assistive driving functions.

A conventional electronic circuit for powering multiple electronic systems of the ECU of the vehicle may require one of the SoCs, e.g. SoC1, to power-on and complete its boot-up process before the other SoCs, e.g. SoC2 and SoC3, in the ECU can be powered on. After SoC1 completes its boot-up process, it may set its output pins to enable the power for SoC2 and SoC3. In this usual sequential power-on configuration, the start-up time of the system equals to T1+MAX (T2, T3), where T1, T2 and T3 are the time required for SoC1, SoC2 and SoC3 to complete their boot up process respectively.

Depending on the complexity of the boot up process of SoC1, the overall boot up time of the system is accumulative to its boot up times of each SoC. If the complexity of SoC2 and SoC3 is already high, the time spent on booting up SoC1 will reduce the available time for SoC2 and SoC3. As a result, it is much more challenging for these SoCs to achieve the short start-up time.

An objective of the present invention is to power-on multiple electronic systems of the ECU of a vehicle in a reduced time.

This objective is achieved by the respective subject-matter of the independent claims.

Further implementations and preferred embodiments are subject-matter of the dependent claims.

According to an aspect of the invention, an electronic circuit for powering multiple electronic systems of an electronic control unit of a vehicle is provided. Therein, the electronic circuit comprises a power input detector, which is configured to detect an input voltage and to generate a first set signal at an output of the power input detector depending on the detected input voltage. The electronic circuit further comprises multiple latches, wherein each of the multiple latches is associated with one of the multiple electronic systems, wherein the output of the power input detector is connected to a respective set input of each of the multiple latches, wherein each of the multiple latches is configured to generate a respective enable signal at an output of the respective latch depending on the first set signal. The electronic circuit further comprises multiple power management circuitries, wherein each of the multiple latches is associated to one of the multiple power management circuitries, wherein each respective output of each of the multiple latches is connected to its associated power management circuitry, wherein each of the multiple power management circuitries is associated to one of the multiple electronic systems and configured to power its associated electronic system depending on the enable signal.

The electronic circuit may be understood as a circuit composed of individual electronic components, for instance discrete electronic components, such as for example resistors, transistors, capacitors, inductors and diodes, but also any kind of electronic systems, subsystems and integrated circuits, which are connected by conductive wires or traces through which electric current can flow.

The multiple electronic systems can be or can comprise two or more, respectively at least two electronic systems. The respective electronic systems can differ from each other in their kind. An electronic system may be programmable. Preferably, an electronic system is or may comprise a microprocessor or a microcontroller-integrated-circuit. The electronic system may also comprise a bus, a clock generator, a memory storage and/or interfaces, respectively at least an input and/or an output.

An electronic system may for example be designed as a System-on-a-Chip (SoC). An SoC may be an integrated circuit (also known as a “chip”) that integrates all or most components of a computer or any other electronic system. These components may include a central processing unit (CPU), memory interfaces, on-chip input/output devices and/or secondary storage interfaces, for example alongside other components such as radio modems and/or a graphics processing unit (GPU)-all on a single substrate or microchip.

The electronic control unit (ECU), also known as an electronic control module (ECM), is for example an embedded system that controls one or more of electrical systems or subsystems, preferably in the vehicle. The ECU may at least comprise a microprocessor or a microcontroller.

The term powering can be understood the providing or supplying with an electric power, respectively an electric voltage and/or an electric current.

Preferably, the ECU is designed for or as a part of an electronic vehicle guidance system, preferably implemented as an Advanced Driver Assistance Systems (ADAS) and/or an Autonomous Driving System (ADS) of a vehicle. An electronic vehicle guidance system may be understood as an electronic system, configured to guide a vehicle in a fully automated or a fully autonomous manner and, in particular, without a manual intervention or control by a driver or user of the vehicle being necessary. The vehicle carries out all required functions, such as steering maneuvers, deceleration maneuvers and/or acceleration maneuvers as well as monitoring and recording the road traffic and corresponding reactions automatically. In particular, the electronic vehicle guidance system may implement a fully automatic or fully autonomous driving mode according to level 5 of the SAE J3016 classification. In particular, the electronic vehicle guidance system may implement a partly automatic or partly autonomous driving mode according to levels 1 to 4 of the SAE J3016 classification. Here and in the following, SAE J3016 refers to the respective standard dated June 2018.

Guiding the vehicle at least in part automatically may therefore comprise guiding the vehicle according to a fully automatic or fully autonomous driving mode according to level 5 of the SAE J3016 classification. Guiding the vehicle at least in part automatically may also comprise guiding the vehicle according to a partly automatic or partly autonomous driving mode according to levels 1 to 4 of the SAE J3016 classification.

The power input detector may be one electronic component of the electronic circuit or may be at least composed of individual electric or electronic components. Once an input voltage is supplied to a power input of the electronic circuit, respectively the ECU, the power input detector may detect said input voltage immediately and/or instantly. In direct or indirect consequence, the power input detector may generate the first set signal at an output of the power input detector immediately and/or instantly. Preferably, the switching on the input voltage and generating the first set signal happens nearly simultaneously. The input voltage may be supplied by a superordinate power supply system of the vehicle and may be provided by an auxiliary battery or a generator of the vehicle.

The output of the power input detector may preferably be an output interface which is connected to the respective set inputs or set input interfaces of each latch by electric traces or wires.

A latch, sometimes also denoted as a flip-flop, in particular level controlled flip-flop, is an electronic circuit that may provide two stable signal states and can be used to store that state. Preferably, the multiple latches may each be a device which stores a single bit (binary digit) of data, wherein one of its two states may represent a “one” and the other may represent a “zero”. Such data storage can be used for storage of state, and such a circuit is described as sequential logic in electronics. The latch may comprise a set input, a reset input and an output.

Each latch may for example operated as follows. If the latch receives a respective set signal at its set input, the latch will generate or set the enable signal at its output and keep the enable signal until the latch receives a reset signal at its reset input. According to that, the enable signal is preferably a permanent signal. If the latch receives a respective reset signal at its reset input, the latch will switch off or disable or reset the enable signal until the latch receives a set signal at its set input.

The multiple latches may for example be designed as SR NOR latches, wherein the output states remain constant while set and reset input signals are both low. If S (Set Input) is pulsed high while R (Reset Input) is held low, then Q (Output) of the latch is forced high, and stays high when S returns to low so that the enable signal is set. Similarly, if R is pulsed high while S is held low, then Q is forced low, and stays low when R returns to low so that the enable signal is reset. Other designs can also be used for a latch as well. The set input and the reset input of each latch may be active low inputs. Therefore, the active low signal pulse will activate the latch to output an active high signal at the Q output pin. This high signal output from the latches can keep the PMICs to output the power supplies to their respective SoCs. Therefore the power to all these SoCs is enabled after the set signal of the power input detector is generated.

The enable signal may represent a binary “one” signal. This means, if the latch receives the set signal it will generate a binary “one”, or set the enable signal to a binary “one” at its output immediately and/or instantly. If the latch receives the reset signal it will generate a binary “zero”, or, in other words, switches off or resets the enable signal to a binary “zero” at its output immediately and/or instantly. It is also conceivable that the enable signal may represent a binary “zero” signal when set, wherein the output will generate a binary “one” if it receives a reset signal.

Therein, the set signal may be the first set signal and/or a second set signal and/or a third set signal and so on. The first reset signal may be the first reset signal and/or a second reset signal and/or a third reset signal and so on.

The multiple latches can be or can comprise two or more, respectively at least two latches. The multiple power management circuitries can be or can comprise two or more, respectively at least two power management circuitries. Preferably, the number of latches equals the number of power management circuitries and/or equals the number of electronic systems. Preferably, the number of power management circuitries equals the number of electronic systems. Thus, each latch may be associated with, respectively assigned to, exactly one electronic system and/or exactly one power management circuitry. Each electronic system may be associated with, respectively assigned to, exactly one power management circuitry.

A power management circuitry, also referred to as PMC, may be designed as a Power Management Integrated Circuit (PMIC). Each PMC may be an integrated circuit that can be used to manage the power requirements of each electronic system. Each PMC may be a solid-state device which may also allow to control the flow and direction of electrical current and/or the size of the electrical voltage. Preferably, each PMC comprises one or several DC/DC converters to convert an input voltage to several operating voltages of the electronic system. It may also be possible, that the multiple power management circuitries are structurally combined into one power management circuitry.

Each PMC may power exactly one associated electronic system. To power means that each PMC may supply the electronic system with at least one, preferably multiple, electrical currents and/or multiple operating voltages which are necessary to electrically maintain or run the electronic system. If, respectively as long as the PMC receives the enable signal from its associated latch, preferably at a respective enable interface or pin of the PMC, the PMC will power its associated electronic system continuously. Once the PMC receives the enable signal, it will power the associated electronic system immediately. Once the PMC does not receive the enable signal anymore, it will discontinue to power the electronic system.

An advantage of the invention is that the electronic circuit allows parallel boot up of multiple electronic systems, for example SoCs, e.g. in an automotive ECU, so that a startup time of the ECU is reduced significantly compared to an at least partially sequential boot up of multiple electronic systems. All of the multiple electronic systems are advantageously powered simultaneously and boot up simultaneously. As a result, the ECU is available very early when activated and can thus help to further improve systems in a vehicle.

According to several implementations, a reset input of each of the multiple latches is connectable or connected to a first output of the associated electronic system. Preferably, each latch of the multiple latches is configured to switch off the enable signal depending on a first reset signal at the respective reset input.

As already described, the enable signal generated at the output of the latch may be a permanent signal representing a binary “one”. Switching off or resetting the enable signal may mean that a binary “zero” is generated at the output of the latch. A reverse logic is equally conceivable.

By switching off the enable signal the PMC may stop powering its associated electronic system, so that the electronic system is switched off. Thus, the electronic system no longer provides services. By connecting the first output of the electronic systems with the associated reset input of the latch, it can be ensured that each electronic system can switch off itself by resetting the latch.

An advantage of this is that each electronic system can be switched off or powered off independently from the other electronic systems or independently from the ECU. This means that not all electronic systems have to be active or all electronic systems have to be inactive. Thus, those electronic systems whose services are not currently needed can be switched off. This saves power in particular. For instance, when the vehicle is stopped with its powertrain off, there is no driving function required so that the corresponding electronic system(s) can be switched off.

According to several implementations, the first set signal and/or the first reset signal comprises a momentary signal pulse, preferably an active low signal pulse. Preferably the first set signal and/or the first reset signal is a, preferably single, momentary signal pulse.

A momentary signal pulse in signal processing is a rapid, transient change in the amplitude of a signal from a baseline value to a higher or lower value, followed by a rapid return to the baseline value, wherein the baseline value is preferably the value of a voltage of the signal. An active low signal pulse may comprise the said change in the amplitude from the baseline value to the lower value, preferably to a ground value, and back to the baseline value, wherein this pulse activates or sets the respective latch when received at the set input of the latch, or respectively deactivates or resets the respective latch when received at the reset input of the latch.

An advantage of the momentary signal pulse as the set signal or reset signal is that a wanted or unwanted reset of a transmitter of the signal, for instance the power input detector or an electronic system or any other computing unit, can technically not result in a set signal or reset signal, so that no unwanted setting or resetting of the latch will occur.

Since the enabling signals for the PMICs are the outputs from the latches, these signals remain high to enable the PMICs outputs unless the latches are reset by signals from the electronic systems.

For instance, if there is a fault in the first electronic system that leads to its self-reset, the outputs of the first electronic system may also be reset. This will lead to those outputs to be reset to an input with high impedance. Since the driving signals to the latches are open-drain active low signals, the reset of the first electronic system that changes its ports to high impedance input will not result in any unwanted active low driving signals to either the set or reset inputs of the latches. Therefore, the outputs of the latches remain unchanged even if an electronic system undergoes a reset.

This is a very important feature to allow other electronic systems in the system to perform their tasks when one or more of the electronic systems are faulty, in order to minimize the level of incapability of the ECU when unwanted faulty cases happen.

According to several implementations, the electronic circuit further comprises a computing unit, which is connected to the set input of a first latch of the multiple latches and configured to generate a second set signal. Preferably, the first latch is configured to generate the respective enable signal depending on the second set signal.

The multiple latches comprises the first latch and may comprise a second latch, a third latch, and so on. In accordance with that, the first latch is associated with a first power management circuitry and with a first electronic system, the second latch is associated with a second power management circuitry and with a second electronic system, and the third latch is associated with a third power management circuitry and with a third electronic system, and so on, wherein the respective number is not limited to three.

The computing unit may be a processor core. An output of the computing unit may be connected to the set input of the first latch, at which the output of the power input detector is also connected. Preferably, the output of the computing unit and the power input detector may be connected to the set input by an OR gate. This means, that the set input will receive the set signal if the computing unit or the power input detector generates the respective set signal at their respective output. If the first latch receives the second set signal at its set input, it will generate the enable signal at its output, so that the first power management circuitry is enabled. Consequently, the first electronic system will be powered and boot up. Preferably, the computing unit may always be booted up when the input voltage is applied to the electronic circuit or to the ECU.

This advantageous connection ensures that the first electronic system can be switched on independently from any other electronic system. This means that in a state where only the services of the first electronic system are needed, only the first electronic system will be booted, so that the other electronic systems can remain deactivated and thus power can be saved. Further, it is also advantageous that all electronic systems may be switched off when their services are not needed so that power can be saved.

According to several implementations, the electronic circuit comprises the multiple electronic systems. Preferably, the first electronic system of the multiple electronic systems, which is associated to the first latch, comprises the computing unit.

Preferably, the computing unit is integrated into the first electronic system. Preferably, one component, e.g. one processor core, of the electronic system may be designated to be the first computing unit. This brings the advantage that no additional components are needed in the electronic circuit, but a part of the first electronic system can embody this component. Another advantage of this arrangement is that the first electronic system does not have to be permanently fully booted up, but only the computing unit.

According to several implementations, a second output of the first electronic system is connected to the set input of a second latch of the multiple latches, which is different from the first latch. Preferably, the second output of the first electronic system is connected to an OR gate at the set input of the second latch. Preferably the first electronic system is configured to generate a third set signal, wherein the second latch is configured to generate the respective enable signal depending on the third set signal. This may result in the second PMC receiving the enable signal and powering the second electronic system.

Preferably, further outputs of the first electronic system may each be connected to a respective set input of further latches so that further electronic systems may be powered. The advantage that results from this is that the first electronic system can activate all other electronic systems independently. In this way, those electronic systems that are needed for a particular state can be activated in a targeted manner. This continues to save power.

According to several implementations, a third output of the first electronic system is connected to the reset input of the second latch, wherein the first electronic system is configured to generate a second reset signal, wherein the second latch is configured to switch the respective enable signal depending on the second reset signal. This may result in the second PMC ending the powering of the second electronic system.

Preferably, the third output of the first electronic system and the respective first output of the second electronic system may be connected to the reset input by an OR gate. This means, that the reset input will receive the reset signal if the first electronic system or the second electronic system generates the respective reset signal at their respective output. If the second latch receives the respective reset signal at its reset input, it will switch off the enable signal at its output, so that the second power management circuitry is disabled. Consequently, the second electronic system will be powered off. Preferably, further outputs of the first electronic system may each be connected to a respective reset input of further latches so that further electronic systems may be powered off.

In other words, while it is possible to set the latch outputs to enable the power for respective electronic systems, it is also possible to reset the latch outputs so that the power of the respective PMICs can be disabled so that the respective electronic systems can be powered off.

The latches can facilitate independent power off of respective electronic systems. For example, all electronic systems are power-on after receiving the first set signal that sets the latch outputs to high. If an application use case occurs that does not need the third electronic system, the third electronic system can be powered off by resetting the third latch connecting to the third PMC. The reset input of the latch for the third PMC is connected to an output of the first electronic system, an output of the second electronic system as well as an output of the third electronic system. These outputs are all designed to be open-collector or open-drain output, so that they can be connected together to the same reset input of the latch. If the first electronic system is the host of the ECU, its output can be set to an active low pulse to reset the latch. The latch output will become low, and the PMC will stop powering the third electronic system so that the third electronic system can be powered off.

Since the enabling signals for the PMCs are the outputs signals from the latches, these signals remain at the previous state unless the respective latch outputs are set or reset by active low pulses.

Therefore, an electronic system can be powered on or powered off independently from other electronic systems. In this way, those electronic systems that are no longer needed for a particular state can be deactivated in a targeted manner. This improves the ECU further to save power. For example, the third electronic system can be powered on by the power input detector and the second electronic system, and be powered off by the first electronic system, the second electronic system, and the third electronic system itself. If the third electronic system is powered off by the first electronic system after it is powered on by the power input detector, the first electronic system does not need to stay in powered mode to sustain the power-on state of the third electronic system. Therefore, it is feasible to power off the electronic system according to a specific use case of the vehicle.

This is particularly useful for applications where independent firmware updates to the electronic systems are required. Since each electronic system under firmware update may undergo multiple resets during the firmware update process, if a reset of a particular electronic system affects the other electronic systems in the ECU, a recovery process will be required to allow the electronic systems in the ECU to resume the update activity from its previous firmware update stage. This will complicate the firmware update process and may result in an undesirable longer firmware update duration.

According to several implementations, the electronic circuit comprises a power supply unit, which is connected to a power input of the electronic circuit and configured to supply the power input detector and/or the multiple latches and/or the computing unit with an operating voltage derived from the input voltage provided by the power input.

Preferably, the power supply unit may be or may comprise a DC/DC converter to convert the input voltage to a preferred operating voltage. The advantage of this is that the power input detector, as well as the multiple latches and the computing unit, can be supplied directly and simultaneously with supply voltage without any loss of time and can perform their respective tasks as soon as an input voltage is applied. This can further accelerate the operational readiness of the ECU.

According to several implementations, each of the multiple power management circuitries is connected to the power input and configured to provide an operating voltage to the respective associated electronic system derived from the input voltage provided by the power input. Preferably, the PMCs may be connected in parallel to each other so that the PMICs are supplied simultaneously with input voltage. This can advantageously ensure a shortened start-up time.

Preferably, a second power supply unit, preferably a switched-mode power supply (SMPS) is interposed between the PMC and the power input. Preferably, the second power supply unit may be or may comprise a DC/DC converter to convert the input voltage to a regulated voltage of which may be preferably lower than a voltage level of the input voltage.

According to several implementations, the output of the power input detector and/or the first output and/or the second output and/or the third output comprises an open drain circuit or an open collector circuit, which are configured to provide the momentary signal pulse.

Preferably, all outputs of each electronic system that are connected to a reset input or a set input of any latch, may be or may comprise an open drain circuit or an open collector circuit. Preferably, all those outputs that are connected to one set input or reset input are linked by an OR gate.

An open collector circuit behaves like a switch that is either connected to ground or disconnected. Instead of outputting a signal of a specific voltage or current, the output signal is applied to a base of an internal NPN transistor whose collector is externalized (open) on the respective output. An emitter of the NPN transistor is connected internally to a ground pin. If the output device is a MOSFET the output is called open drain and it functions in a similar way.

An advantage of such an output is that it can provide an output signal suitable to be connected to an input via an OR gate. Furthermore, it is advantageously ensured that a signal is not incorrectly output in the event of an intended or not intended reset of the corresponding electronic system.

According to several implementations, each of the multiple electronic systems comprises one or more processor cores. Each processor core may be configured to fulfil a respective task within the ECU and may be switched on or off when needed.

According to a further aspect of the invention, a method for powering multiple electronic systems in an electronic control unit of a vehicle is provided. The method comprises the steps of:
switching on input voltage to the electronic control unit;
detecting the switched on input voltage and generating a first set signal depending on the detected input voltage by a power input detector;
receiving the first set signal by each of multiple latches, in particular at a respective set input of each of the multiple latches, and generating a respective enable signal depending on the first set signal by each of the multiple latches;
receiving the respective enable signal by a respective power management circuitry and providing power to a respective electronic system of the multiple electronic systems depending on the respective enable signal.

The method according to the invention may be carried out by an electronic circuit, preferably according to an aspect of the invention. The electronic circuit comprises the power input detector, which is configured to detect an input voltage and to generate a first set signal at an output of the power input detector depending on the detected input voltage. The electronic circuit further comprises the multiple latches, wherein each of the multiple latches is associated with one of the multiple electronic systems, wherein the output of the power input detector is connected to a respective set input of each of the multiple latches, wherein each of the multiple latches is configured to generate a respective enable signal at an output of the respective latch depending on the first set signal. The electronic circuit further comprises the multiple power management circuitries, wherein each of the multiple latches is associated to one of the multiple power management circuitries, wherein each respective output of each of the multiple latches is connected to its associated power management circuitry, wherein each of the multiple power management circuitries is associated to one of the multiple electronic systems and configured to power its associated electronic system depending on the enable signal.

Preferably, the input voltage is switched on by a superordinate system of the vehicle that may control the power management of the auxiliary systems of the vehicle at a power input of the ECU or of the electronic circuit according to the invention. Preferably, the first set signal is generated by the power input detector immediately, once the power is switched on. Providing power may also be referred to as powering.

An advantage of the method according to the invention is that the method allows parallel boot up of multiple electronic systems, e.g. in an automotive ECU, so that a startup time of the ECU is reduced significantly compared to an at least partial sequential boot up of multiple electronic systems. All of the multiple electronic systems are advantageously powered simultaneously and boot up simultaneously. As a result, the ECU is available very early in comparison when activated and can thus help to further improve systems in a vehicle.

According to several implementations, each of the multiple latches receives the first set signal from the power input detector in parallel. Advantageously, the first set signal is received by each of the multiple latches immediately and simultaneously.

According to several implementations, the respective enable signal is switched off when a respective reset signal is received by a respective latch of the multiple latches, wherein the respective reset signal is generated by a respective electronic system corresponding to the respective latch. The respective reset signal may also be generated by an electronic system which is different to the corresponding system.

An advantage of this is that each electronic system can be switched off or powered off independently from the other electronic systems or independently from the ECU. This means that not all electronic systems have to be active or all electronic systems have to be inactive. Thus, those electronic systems whose services are not currently needed can be switched off. This saves power in particular. For instance, when the vehicle is stopped with its powertrain off, there is no driving function required so that the corresponding electronic system(s) can be switched off.

Further implementations of the method according to the invention follow directly from the various embodiments of the electronic circuit according to the invention and vice versa. In particular, individual features and corresponding explanations relating to the various implementations of the method according to the invention can be transferred analogously to corresponding implementations of the electronic circuit according to the invention. In particular, the electronic circuit according to the invention may be or is designed or programmed to carry out the method according to the invention. In particular, the electronic circuit according to the invention carries out the method according to the invention.

According to a further aspect of the invention, an electronic control arrangement for a vehicle is provided. The electronic control arrangement comprises an electronic circuit according to any of the claims 1 to 11 an electronic control unit, wherein the electronic control unit comprises the multiple electronic systems. Alternatively, the electronic control arrangement comprises an electronic control unit, which comprises an electronic circuit according to any of the claims 1 to 11, wherein the electronic circuit comprises the multiple electronic systems.

Further features of the invention are apparent from the claims, the figures and the figure description. The features and combinations of features mentioned above in the description as well as the features and combinations of features mentioned below in the description of figures and/or shown in the figures may be comprised by the invention not only in the respective combination stated, but also in other combinations. In particular, embodiments and combinations of features, which do not have all the features of an originally formulated claim, are also comprised by the invention. Moreover, embodiments and combinations of features which go beyond or deviate from the combinations of features set forth in the recitations of the claims are comprised by the invention.

In the figures:

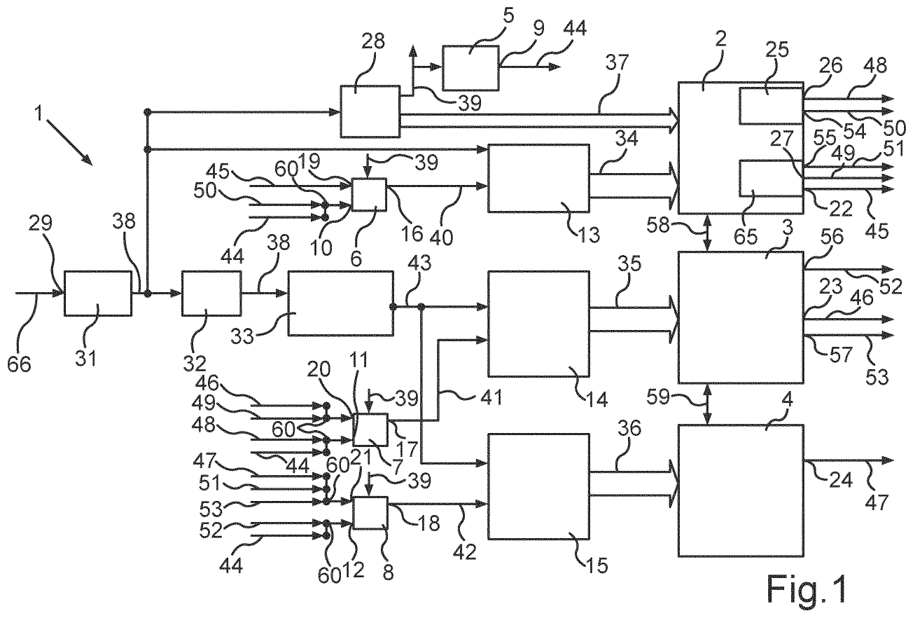

FIG. 1 shows schematically an exemplary implementation of an electronic circuit according to the invention;

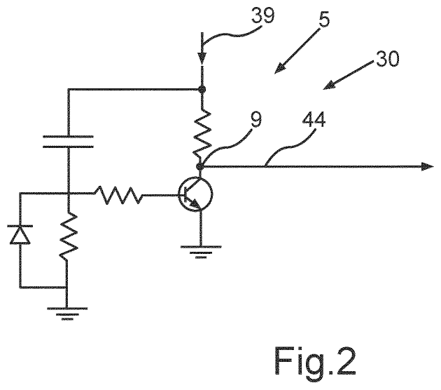

FIG. 2 shows schematically an exemplary implementation of an open drain circuit for use of generating a momentary signal pulse, according to the invention;

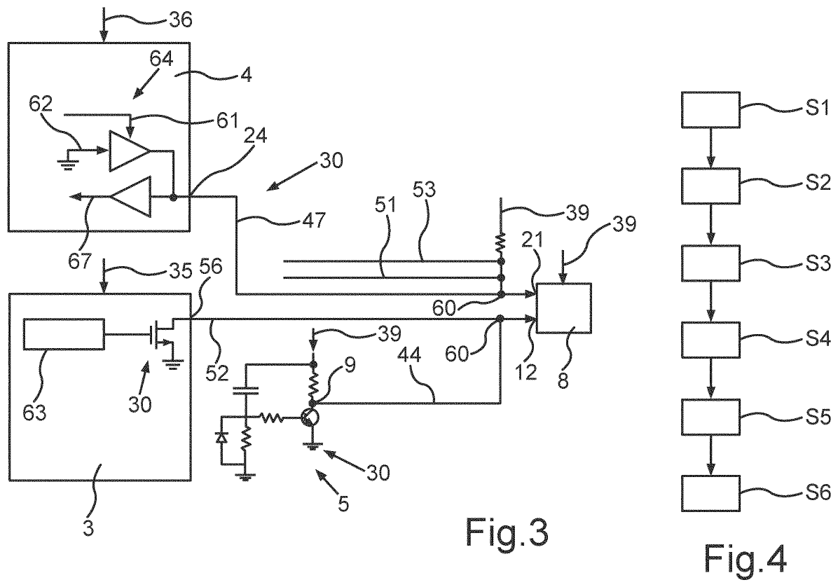

FIG. 3 shows schematically a part of a further exemplary implementation of an electronic circuit according to the invention;

FIG. 4 shows a process flow chart of an exemplary method according to the invention;

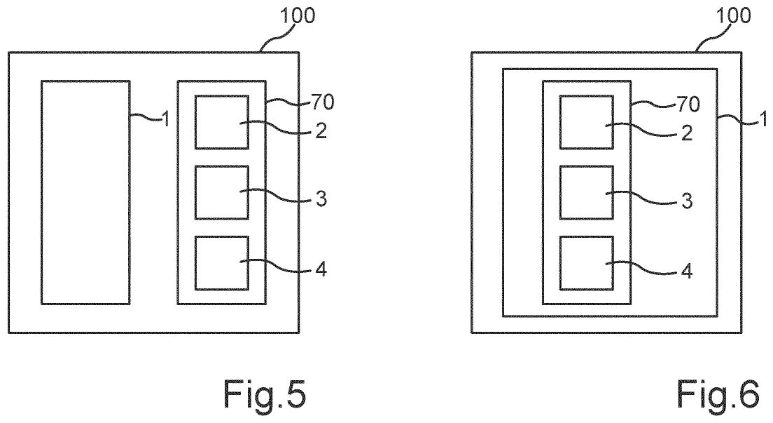

FIG. 5 shows an electronic control arrangement for a vehicle according to an embodiment of the invention;

FIG. 6 shows an electronic control arrangement for a vehicle according to an alternative embodiment of the invention.

FIG. 1 shows an electronic circuit 1 according to the invention. In this example, the electronic circuit 1 comprises or is connected to three electronic systems 2, 3, 4 (also referred to as electronic systems) of an electronic control unit 70 (ECU), wherein the number of electronic systems 2, 3, 4 is not limited to this number. Each of the electronic systems 2, 3, 4 may be powered by a respective power management circuitry 13, 14, 15 (also referred to as PMC) via multiple power rails 34, 35, 36.

A power input 29 may supply an input voltage through an input voltage line 66 via a protection device 31, e.g. a fuse 31. The input voltage line 66 may be connected to an internal input power line 38 of the electronic circuit 1 to which the PMC 13, 14, 15 may be connected in parallel, directly or indirectly. The first PMC 13 is connected directly to the input power line 38, in this example. The second PMC 14 and the third PMC 15 are connected indirectly to the input power line 38 via a second power supply unit 33 (also referred to as SMPS), which can be arranged as a switched-mode power supply (SMPS) 33. The input voltage may also be modified by an electronic filter 32, which is capable of reducing or eliminating unwanted signal components. The filter 32 may be interconnected between the SMPS 33 and the power input 29. Other arrangements of the filter 32 are also possible. The SMPS 33 may provide regulated voltage via a regulated power line 43 to the second PMC 14 and third PMC 15 in parallel. The first PMC 13 may be of a different kind compared to the second PMC 14 and the third PMC 15 as it is able to operate without the SMPS 33.

A first power supply unit 28 may also be connected in parallel to the second power supply unit 33, and may also be referred to as Pre-Regulator, or Pre-Reg 28. The Pre-Reg 28 may provide a first operating voltage (voltage at the common collector, VCC1) at its output via an operating voltage line 39. The operating voltage line 39 may connect a power input detector 5 and multiple latches 6, 7, 8 in parallel to each other. The Pre-Reg 28 may also provide a standby voltage to a computing unit 25 via standby power rails 37 continuously as long as the Pre-Reg 28 is provided with input voltage so that the computing unit 28 is always active when input power is supplied to the electronic circuit 1. The first electronic system 2 may preferably comprise the computing unit 25.

The power input detector 5 is configured to detect the input voltage that is supplied to the electronic circuit 1, preferably indirectly by detecting the first operating voltage which is derived from the input voltage. Once the input voltage is detected by the power input detector 5, it will generate a first set signal at an output 9 of the power input detector 5.

The output 9 is connected to each set input 10, 11, 12 of each of the multiple latches 6, 7, 8 via a first signal line 44, wherein the set inputs 10, 11, 12 are connected in parallel to each other.

When a set signal is received at the respective set input 10, 11, 12, the respective latch 6, 7, 8 may immediately generate a respective enable signal at the respective output 16, 17, 18. The respective enable signal may be directed to the respective PMC 13, 14, 15 via the enable signal lines 40, 41, 42 in order to enable the respective PMC 13, 14, 15. Due to the received enable signal, the respective PMC 13, 14, 15 will provide multiple operating voltages to the respective electronic system 2, 3, 4 via the multiple power rails 34, 35, 36 so that the multiple electronic systems 2, 3, 4 are able to boot up in parallel.

The first electronic system 2 may be configured to be the management master of the ECU 70 in order to manage and monitor the power and health of the components of the ECU 70, especially the second electronic system 3 and the third electronic system 4. Therefore, the first electronic system 2 may be capable of switching on and/or off itself as well as the second electronic system 3 and the third electronic system 4 independently. Preferably, the first computing unit 25 of the first electronic system 2 is capable of generating a set signal at a second output 26 and/or at a fourth output 54 of the first electronic system 2. The second output 26 may be connected to the set input 11 of the second latch 7 via a fifth signal line 48. The fifth signal line 48 and the first signal line 44 may be connected by an OR gate 60 to the set input 11 so that the second latch 7 will set the enable signal at the output 17 either due to a set signal from the power input detector 5 or due to a set signal from the first electronic system 2.

The fourth output 54 may be connected to the set input 10 of the first latch 6 via a seventh signal line 50. The seventh signal line 50 and the first signal line 44 may be connected by an OR gate 60 to the set input 10 so that the first latch 6 will set the enable signal at the output 16 either due to a set signal from the power input detector 5 or due to a set signal from the first electronic system 2.

Preferably, a second computing unit 65, which may be a component of the first electronic system 2, is capable of generating a reset signal at a first output 22 and/or at a third output 27 and/or at a fifth output 55 of the first electronic system 2. The first output 22 may be connected to a reset input 19 of the first latch 6 via a second signal line 45 so that the first latch 6 will reset or switch off the enable signal at the output 16 due to a reset signal from the first electronic system 2. The third output 27 may be connected to a reset input 20 of the second latch 7 via a sixth signal line 49. The fifth output 55 may be connected to a reset input 21 of the third latch 8 via an eighth signal line 51.

The second electronic system 3 may be configured to be superior to the third electronic system 4 and may comprise a processor for computation capabilities, e.g. for automatically driving the vehicle. Therefore, the second electronic system 3 may be capable of switching off itself as well as the third electronic system 4 and switching on the third electronic system 4 independently. Preferably, the second electronic system 3 is capable of generating a set signal at a second output 56. The second output 56 may be connected to the set input 12 of the third latch 8 via a ninth signal line 52. The ninth signal line 52 and the first signal line 44 may be connected by an OR gate 60 to the set input 12 so that the third latch 8 will set the enable signal at the output 18 either due to a set signal from the power input detector 5 or due to a set signal from the second electronic system 3. Preferably, the second electronic system 3 is capable of generating a reset signal at a first output 23. The first output 23 may be connected to the reset input 20 of the second latch 7 via a third signal line 46. The third signal line 46 and the sixth signal line 49 may be connected by an OR gate 60 to the reset input 20 so that the second latch 7 will reset the enable signal at the output 17 either due to a reset signal from the first electronic system 2 or due to a reset signal from the second electronic system 4. Preferably, the second electronic system 3 is capable of generating a reset signal at a third output 57. The third output 57 may be connected to the reset input 21 of the third latch 8 via a tenth signal line 53.

The third electronic system 4 may be subordinate to the second electronic system 3 and the first electronic system 2 and may comprise a processor for computation capabilities, e.g. for assisting a driver at a parking maneuver of the vehicle. Therefore, the third electronic system 4 may be configured to switch off itself, e.g. when the parking maneuver is completed. Preferably, the third electronic system 3 is capable of generating a reset signal at a first output 24. The first output 24 may be connected to the reset input 21 of the third latch 8 via a fourth signal line 47. The fourth signal line 47, the eighth signal line 51 and the tenth signal line 53 may be connected by an OR gate 60 to the reset input 21 so that the third latch 8 will reset the enable signal at the output 18 either due to a reset signal from the first electronic system 2 or due to a reset signal from the second electronic system 3 or due to a reset signal from the second electronic system 3.

In this example, the first electronic system 2 may be able to communicate with the second electronic system 3 via a first communication line 58, and the second electronic system 3 may be able to communicate with the third electronic system 4 via a second communication line 59. The first electronic system 2 may be able to communicate with the third electronic system 4 indirectly by the second electronic system 3 or directly via a third communication line, which is not shown in FIG. 1.

FIG. 2 shows schematically an exemplary implementation of an open drain circuit 30 or an open collector circuit 30 of the power input detector 5 for use of generating momentary signal pulse, preferably an active low signal pulse, according to the invention. The output 9 of the power input detector 5 may comprise or may be or may be designed as an open drain circuit 30. The first outputs 22, 23, 24, the second outputs 26, 56, the third outputs 27, 57, the fourth output 54, and the fifth output 55 of the multiple electronic systems 2, 3, 4 may also be designed as an open drain circuit 30.

When the input voltage, respectively the first operating voltage (VCC1) is applied to the electronic circuit 1 via the operating voltage line 39, the open drain circuit 30 of the power input detector 5 charges up the capacitor in the circuit via the series resistor. The voltage across the series resistor will decrease from VCC1 to zero gradually when the series capacitor continues to charge up. This voltage will drive the transistor to turn-on, and therefore pull the voltage at the collector (respectively the output 9) of the transistor to low. The transistor turns off when the voltage across the series resistor reaches a threshold voltage that cannot turn on the transistor. Therefore an active low voltage pulse is generated at the output 9 that may be received by the multiple latches 6, 7, 8 via the first signal line 44.

FIG. 3 shows schematically a part of an exemplary implementation of an electronic circuit 1 according to the invention. In this example, the output 56 of the second electronic system 30 is designed as an open drain circuit 30 or open collector circuit 30. The transistor of the open drain circuit 30 of the second electronic system 3 may be activated by an internal drive signal unit 63 of the second electronic system 3.

The first output 24 of the third electronic system 4 is not designed as a generic open-drain circuit output 30, in this example, but as a push-pull-output 64. It allows an open-drain-like active output 24 by setting the port pin as output port with low output, which means that the first output 24 may be switched to be connected to a first output line 61 which supplies an operating voltage and may be switched to be connected to ground via a second output line 67. By switching from the first output line 61 to the second output line 62 and back, an active low pulse can be generated. Alternatively, the open-drain-like first output 24 can be an input by setting the port pin as input port via input line 67.

FIG. 4 shows a process flow chart of an exemplary method according to the invention. In a first step S1 an input voltage is switched on to the electronic control unit 70. In a second step S2 the switched on input voltage is detected and a first set signal depending on the detected input voltage by a power input detector 5 is generated. In a third step S3 the first set signal is received by each of multiple latches 6, 7, 8. In a fourth step S4, a respective enable signal is generated depending on the first set signal by each of the multiple latches. In a fifth step S5 the respective enable signal is received by a respective power management circuitry 13, 14, 15. In a sixth step S6 power is provided to a respective electronic system 2, 3, 4 of the multiple electronic systems 2, 3, 4 depending on the respective enable signal.

FIG. 5 shows an electronic control arrangement 100 for a vehicle according to an embodiment of the invention. The electronic control arrangement 100 comprises an electronic circuit 1 and an electronic control unit 70, wherein the electronic control unit 70 comprises the multiple electronic systems 2, 3, 4.

FIG. 6 shows an electronic control arrangement 100 for a vehicle according to an alternative embodiment of the invention. The electronic control arrangement 100 comprises an electronic control unit 70, which comprises an electronic circuit 1 according to any of the claims 1 to 11, wherein the electronic circuit 1 comprises the multiple electronic systems 2, 3, 4.

Various implementations of the invention are directed to a circuit implementation to allow parallel boot up and independent shut-down of multiple electronic systems in an Automotive ECU. The circuit implementation also allows independent resets of the multiple electronic systems in the ECU.

The implementation makes use of multiple latches, and, for example, open-drain/open-transistor driving circuits to achieve the parallel boot-up, independent shut-down and independent resets.

For example, the output signal of a circuit, in particular the power input detector, that detects the instance of power input to the ECU may be used as the set signal to enable multiple independent power supplies of multiple electronic systems. Therefore, these electronic systems in the ECU do not need to wait for one of the electronic systems to boot up before their powers are enabled by the booted electronic system. They can start in parallel to achieve the shortest possible time for boot completion, and to serve the end user application accordingly.

The set signal is for example a momentary signal pulse. This signal pulse may be latched to become different enable signals to multiple power supplies for multiple electronic systems.

There may be other sources of set signals to power on the electronic systems in the ECU. These signal pulses may be logically ORed to the inputs of the latches so that if any one of these set signals is active, it will enable the power to the respective electronic system. All the driving pulses mentioned above may be for example negative pulses. This combined with the latched design also prevents an electronic system in the ECU from unwanted power-on or power-off due to unwanted changes of the driving signal from other electronic systems in the ECU. This can facilitate the use of open-drain and open-collector circuits to implement AND or OR logics easily without complicated circuit components. This open-drain driving circuit design also can make sure that the output states of the latches are unchanged as there is no set signal output to the inputs of the latches when an electronic system is powered off.

While latches may be utilized to keep the enable signals for keeping power-on the supplies, there may also be multiple disable or reset signals that are logically ORed to the latches to disable the outputs of the latches. This allows each electronic system to be powered off by itself, or other sources that are allowed to power off the electronic system.

For reset signals to the electronic systems in the ECU, these reset signals may for example all be designed in open-drain or open-collector configurations to prevent uncontrolled reset signals from an electronic system due to its own reset process.

Various embodiments may have the advantage that the first electronic system does not have to be active all the time. Although it may make sense to keep the first electronic system active during the time when the ECU is required to deliver safe driving functions, there may also be modes of operation for the ECU that do not require all the electronic systems to be active. For instance, when the vehicle is stopped with its powertrain off, there is no driving function required. The ECU can for example undergo a firmware update during this operating condition. During firmware update, the first electronic system can undergo multiple resets before it completes its firmware update process. Various embodiments may have the advantage that a reset of the first electronic system will not unconditionally power-off the second electronic system and the third electronic system, for example, when the second electronic system and the third electronic system may also be in their firmware update processes. Consequently, the ECU may not require a recovery process to allow the second electronic system or the third electronic system to recover their firmware update processes. Therefore the firmware update processes of the electronic systems in the ECU can be completed independently.

1. An electronic circuit for powering multiple electronic systems of an electronic control unit of a vehicle, the electronic circuit comprising:
a power input detector, which is configured to detect an input voltage and to generate a first set signal at an output of the power input detector depending on the detected input voltage;
multiple latches,
wherein each of the multiple latches is associated with one of the multiple electronic systems,
wherein the output of the power input detector is connected to a respective set input of each of the multiple latches,
wherein each of the multiple latches is configured to generate a respective enable signal at an output of the respective latch depending on the first set signal; and
multiple power management circuitries
wherein each of the multiple latches is associated to one of the multiple power management circuitries
wherein each respective output of each of the multiple latches is connected to its associated power management circuitry,
wherein each of the multiple power management circuitries is associated to one of the multiple electronic systems and configured to power its associated electronic system depending on the enable signal.

2. The electronic circuit according to claim 1, further comprising a reset input of each of the multiple latches, wherein the reset input is connectable to a first output of the associated electronic system wherein each latch of the multiple latches is configured to switch off the enable signal depending on a first reset signal at the respective reset input.

3. The electronic circuit according to claim 2, wherein the first set signal and/or the first reset signal comprises a momentary signal pulse, preferably an active low signal pulse.

4. The electronic circuit according to claim 1 further comprising a computing unit, which is connected to the set input of a first latch of the multiple latches and configured to generate a second set signal, wherein the first latch is configured to generate the respective enable signal depending on the second set signal.

5. The electronic circuit according to claim 4, further comprising the multiple electronic systems wherein a first electronic system of the multiple electronic systems which is associated to the first latch, comprises the computing unit.

6. The electronic circuit according to claim 5, further comprising a second output is connected to the set input of a second latch of the multiple latches which is different from the first latch, wherein the first electronic system is configured to generate a third set signal, wherein the second latch is configured to generate the respective enable signal depending on the third set signal.

7. The electronic circuit according to claim 6, further comprising a third output of is connected to a reset input of the second latch, wherein the first electronic system is configured to generate a second reset signal, wherein the second latch is configured to switch off the respective enable signal depending on the second reset signal.

8. The electronic circuit according to claim 4, further comprising a power supply unit, which is connected to a power input of the electronic circuit and configured to supply the power input detector and/or the multiple latches and/or the computing unit with an operating voltage derived from the input voltage provided by the power input.

9. The electronic circuit according to claim 8, wherein each of the multiple power management circuitries is connected to the power input and configured to provide an operating voltage to the respective associated electronic system derived from the input voltage provided by the power input.

10. The electronic circuit according to claim 3, wherein the output of the power input detector and/or the first output and/or a the second output and/or a the third output comprises an open drain circuit, which is configured to provide the momentary signal pulse, or an open collector circuit, which is configured to provide the momentary signal pulse.

11. The electronic circuit according to claim 5, each of the multiple electronic systems comprises one or more processor cores.

12. A method for powering multiple electronic systems in an electronic control unit of a vehicle, the method comprising:
switching on an input voltage to the electronic control unit;
detecting the switched on input voltage and generating a first set signal depending on the detected input voltage by a power input detector;
receiving the first set signal by each of multiple latches and generating a respective enable signal depending on the first set signal by each of the multiple latches and
receiving the respective enable signal by a respective power management circuitry and providing power to a respective electronic system of the multiple electronic systems depending on the respective enable signal.

13. The method according to claim 12, wherein each of the multiple latches receives the first set signal from the power input detector in parallel.

14. The method according to claim 12,
wherein the respective enable signal is switched off when a respective reset signal is received by a respective latch of the multiple latches,
wherein the respective reset signal is generated by a respective electronic system associated to the respective latch.

15. An electronic control arrangement for a vehicle, the electronic control arrangement comprises an electronic circuit any comprising:
a power input detector, which is configured to detect an input voltage and to generate a first set signal at an output of the power input detector depending on the detected input voltage;
multiple latches,
wherein each of the multiple latches is associated with one of the multiple electronic systems,
wherein the output of the power input detector is connected to a respective set input of each of the multiple latches.
wherein each of the multiple latches is configured to generate a respective enable signal at an output of the respective latch depending on the first set signal;
multiple power management circuitries, wherein each of the multiple latches is associated to one of the multiple power management circuitries, wherein each respective output of each of the multiple latches is connected to its associated power management circuitry, wherein each of the multiple power management circuitries is associated to one of the multiple electronic systems and configured to power its associated electronic system depending on the enable signal; and
an electronic control unit, wherein the electronic control unit comprises the multiple electronic systems; or
the electronic control arrangement comprises an electronic control unit, which comprises the electronic circuit, wherein the electronic circuit comprises the multiple electronic systems.
